(19) United States
(12) Patent Application Publication
(10) Pub. No.: US 2012/0293278 A1
(43) Pub. Date: Nov. 22, 2012

(54) STACKED BULK ACOUSTIC RESONATOR COMPRISING DISTRIBUTED BRAGG REFLECTOR

(75) Inventors: Dariusz BURAK, Fort Collins, CO (US); Alexandre SHIRAKAWA, San Jose, CA (US); John D. LARSON, III, Palo Alto, CA (US); Paul BRADLEY, Los Altos, CA (US); Richard C. RUBY, Menlo Park, CA (US); Bernhard KOELLE, Milpitas, CA (US); John CHOY, Westminster, CO (US); Kevin J. GRANNEN, Thornton, CO (US)

(73) Assignee: Avago Technologies Wireless IP (Singapore) Pte. Ltd., Singapore (SG)

(21) Appl. No.: 13/112,407

(22) Filed: May 20, 2011

(51) Int. Cl. H03H 9/58

(52) U.S. Cl. 333/189

(57) ABSTRACT

A device comprises a substrate, an acoustic stack, and a distributed Bragg reflector. The acoustic stack comprises a first electrode formed on the substrate, a first piezoelectric layer formed on the first electrode, a second electrode formed on the first piezoelectric layer, a second piezoelectric layer formed on the second electrode, and a third electrode formed on the second piezoelectric layer. The distributed Bragg reflector is formed adjacent to the acoustic stack and provides it with acoustic isolation.

### BACKGROUND

Frequency filters are common components found in most telecommunication devices. Such filters can be used, for instance, to select a frequency band for transmitting or receiving radio frequency (RF) communication signals in a mobile telephone, notebook computer, or other mobile electronic device.

As telecommunications devices evolve to achieve higher performance in smaller form factors, there is a basic need to reduce the size of many of their components, such as the frequency filters. One proposed solution for reducing the size of frequency filters is the adoption of acoustic resonators that selectively transmit certain resonant frequencies according to their physical geometry and electromechanical properties.

FIG. 1 is a block diagram illustrating an example of a band pass filter 100 formed by a plurality of acoustic resonators. Band pass filter 100 has a ladder circuit configuration that can be found, for instance in duplexer circuits associated with transmitters and receivers of mobile telephones.

Referring to FIG. 1, band pass filter 100 comprises a plurality of series resonators 105 and a plurality of shunt resonators 110 connected between an input port and an output port. Series resonators 105 have higher resonant frequencies than shunt resonators 110. Accordingly, they allow higher frequencies to pass through while shunting out lower frequencies.

FIG. 2 is a cross-sectional view illustrating an acoustic resonator 200 that can be included as one of series resonators 105 or shunt resonators 110 in the example of FIG. 1. Acoustic resonator 200 is a film bulk acoustic resonator (FBAR).

Referring to FIG. 2, acoustic resonator 200 comprises a substrate 205 and an acoustic stack 210 formed on substrate 205. Acoustic stack 210 comprises a piezoelectric layer 220 disposed between a first electrode 215 and a second electrode 225. Piezoelectric layer 220 comprises a piezoelectric material that converts electrical energy into mechanical movement and vice versa.

During typical operation, an electrical bias applied between first electrode 215 and second electrode 225 causes piezoelectric layer 220 to expand (or contract, depending on a phase of electrical signal) through the inverse piezo-electric effect. The expansion (or contraction) of piezo-electric layer 220 produces electric charge through the direct piezo-electric effect, which is then presented to the electrodes. Where the frequency of the electrical signal and the natural mechanical resonance frequency of the slab resonator are close to each other, an electro-mechanical resonant state occurs resulting in significant mechanical displacements of particles comprising the stack 210 and significant modification of electrical signal at electrodes 215 and 225. This modification of electrical response is a basis of signal filtering in structure 100 shown in FIG. 1. Where the frequency of the electrical signal is far away from mechanical resonance frequency of the stack 210, the mechanical displacement of particles is negligible and so is the produced charge, thus resulting in a standard capacitor-like electrical response of the resonator 200.

An air cavity 230 is formed in substrate 205 to facilitate mechanical movement of acoustic stack 210. Air cavity 230 facilitates mechanical movement by creating acoustic isolation between acoustic stack 210 and substrate 205. This acoustic isolation prevents acoustic stack 210 from losing mechanical energy to substrate 230, which in turn prevents acoustic stack 210 from losing signal strength.

A microcap 235 is connected to acoustic stack 210 using wafer bonding technology. Microcap 235 can be formed, for instance, by etching a cavity in a silicon wafer and placing the cavity over acoustic stack 210. It can also be formed, for instance, by attaching an annular gasket to substrate 205 and placing silicon over the annular gasket. Microcap 235 forms an air cavity 245 over acoustic stack 210 and allows for unobstructed movement of acoustic stack 210. It also hermetically seals acoustic resonator 200 to prevent damage from environmental factors such as humidity.

In addition to the features shown in FIG. 2, acoustic resonator 200 typically comprises electrical contact pads connected to first and second electrodes 215 and 225. The electrical contact pads extend outward from the sides of acoustic resonator 200 to transmit input and output signals to first and second electrodes 215 and 225, respectively.

Important considerations in designing acoustic resonators include, among other things, cost, chip area, and response characteristics. There are various factors that affect each of these considerations. For instance, the cost of a resonator typically varies according to the materials and processes used in its manufacture. The chip area, meanwhile, tends to vary according to the lateral width of the acoustic stack and associated components, such as the microcap and contact pads. In general, the lateral width of the acoustic stack varies according to its passband, with lower frequency resonators occupying more space than higher frequency resonators.

The response characteristics of an acoustic resonator are defined by various parameters, such as an electro-mechanical coupling coefficient (kₜ²) and a quality (Q) factor. The coupling coefficient kₜ² of each resonator 200 indicates the efficiency of energy transfer between electrodes and the piezoelectric materials, and it affects insertion loss and bandwidth of the filter 100. The Q factor affects roll-off of the filter 100, and it varies according to various material properties of the acoustic resonator 200, such as a series resistance Rs and a parallel resistance Rp, which correspond to various heat losses and acoustic losses of the resonator 200.

In order to further the use and benefits of acoustic resonators in frequency filters and other applications, researchers continue to pursue techniques and technologies for improving their cost, chip area, response characteristics, and other attributes.

### SUMMARY

In a representative embodiment, a device comprises a substrate, an acoustic stack, and a distributed Bragg reflector. The acoustic stack comprises a first electrode formed on the substrate, a first piezoelectric layer formed on the first electrode, a second electrode formed on the first piezoelectric layer, a second piezoelectric layer formed on the second electrode, and a third electrode formed on the second piezoelectric layer. The distributed Bragg reflector is formed on the third electrode.

In another representative embodiment, a device comprises a substrate, a distributed Bragg reflector formed over the substrate, and an acoustic stack formed on the substrate over the distributed Bragg reflector. The acoustic stack comprises a first electrode, a first piezoelectric layer formed on the first electrode, a second electrode formed on the first piezoelectric layer, a second piezoelectric layer formed on the second electrode, and a third electrode formed on the second piezoelectric layer.

In another representative embodiment, a filter comprises a plurality of series connected acoustic resonators between an input terminal and an output terminal, and a plurality of shunt acoustic resonators connected in parallel between the series connected acoustic resonators and a reference voltage. At least one of the series connected acoustic resonators or the shunt acoustic resonators comprises a substrate, an acoustic stack comprising a first electrode formed on the substrate, a first piezoelectric layer formed on the first electrode, a second electrode formed on the first piezoelectric layer, a second piezoelectric layer formed on the second electrode, and a third electrode formed on the second piezoelectric layer, and a distributed Bragg reflector formed on the third electrode.

### BRIEF DESCRIPTION OF THE DRAWINGS

The described embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a block diagram illustrating a conventional band-pass filter comprising a plurality of acoustic resonators.

FIG. 2 is a cross-sectional view illustrating a conventional acoustic resonator.

FIG. 3A is a cross-sectional view illustrating a stacked acoustic resonator comprising a lower Bragg reflector in accordance with a representative embodiment.

FIG. 3B is a top view of the acoustic resonator of FIG. 3A in accordance with a representative embodiment.

FIG. 4 is a cross-sectional view illustrating a stacked acoustic resonator comprising an upper Bragg reflector in accordance with a representative embodiment.

FIG. 5 is a cross-sectional view illustrating a stacked acoustic resonator comprising lower and upper Bragg reflectors in accordance with a representative embodiment.

FIG. 6A is a cross-sectional view illustrating an acoustic resonator having contact pads formed above an acoustic stack in accordance with a representative embodiment.

FIG. 6B is a top view of the acoustic resonator of FIG. 6A in accordance with a representative embodiment.

FIG. 7 is a cross-sectional view illustrating an acoustic resonator having contact pads formed above an acoustic stack in accordance with another representative embodiment.

### DETAILED DESCRIPTION

In the following detailed description, for purposes of explanation and not limitation, representative embodiments disclosing specific details are set forth in order to provide a thorough understanding of the present teachings. However, it will be apparent to one having ordinary skill in the art having had the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical and scientific meanings of the defined terms as commonly understood and accepted in the technical field of the present teachings.

As used in the specification and appended claims, the terms ‘a’, ‘an’ and ‘the’ include both singular and plural referents, unless the context clearly dictates otherwise. Thus, for example, ‘a device’ includes one device and plural devices.

As used in the specification and appended claims, and in addition to their ordinary meanings, the terms ‘substantial’ or ‘substantially’ mean to within acceptable limits or degree.

As used in the specification and the appended claims and in addition to its ordinary meaning, the term ‘approximately’ means to within an acceptable limit or amount to one having ordinary skill in the art. For example, ‘approximately the same’ means that one of ordinary skill in the art would consider the items being compared to be the same.

The drawings and the various elements depicted therein are not drawn to scale. In addition, relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be below that element. The present teachings relate generally to bulk acoustic wave (BAW) resonator structures comprising double bulk acoustic resonators (DBARs). In certain applications, the BAW resonator structures provide DBAR-based filters (e.g., ladder filters). Certain details of DBARs, BAW resonator filters, materials thereof and their methods of fabrication may be found in one or more of the following commonly owned U.S. patents and patent applications: U.S. Pat. No. 6,107,721, to Lakin; U.S. Pat. Nos. 5,587,620, 5,873,153 and 6,507,983 to Ruby, et al.; U.S. patent application Ser. No. 11/443,954, entitled “Piezoelectric Resonator Structures and Electrical Filters” to Ruby, et al.; U.S. patent application Ser. No. 10/990,201, entitled “Thin Film Bulk Acoustic Resonator with Mass Loaded Perimeter” to Feng, et al.; U.S. patent application Ser. No. 11/713,726, entitled “Piezoelectric Resonator Structures and Electrical Filters having Frame Elements” to Jamneala, et al.; U.S. patent application Ser. No. 11/159,753, entitled “Acoustic Resonator Performance Enhancement Using Alternating Frame Structure” to Richard C. Ruby, et al; U.S. patent application Ser. No. 12/490,525 entitled “Acoustic Resonator Structure Comprising a Bridge” to Choy, et al. and filed on Jun. 24, 2009; and U.S. patent application Ser. No. 12/626,035, entitled “Acoustic Resonator Structure Having an Electrode with a Cantilevered Portion” to Choy, et al. and filed on Nov. 25, 2009. Examples of stacked bulk acoustic resonators, as well as their materials and methods of fabrication, may be found in U.S. Patent Application Publication 2010/0052815 of Paul Bradley et al., and published Mar. 4, 2010, U.S. patent application Ser. No. 13/074,094 of Shirakawa et al., and filed on Mar. 29, 2011, U.S. patent application Ser. No. 13/036,489 of Burak et al., and filed on Feb. 28, 2011, and U.S. patent application Ser. No. 13/101,376 of Burak et al., and filed on May 5, 2011.

The disclosures of these patents and patent applications are specifically incorporated herein by reference. It is emphasized that the components, materials and method of fabrication described in these patents and patent applications are representative and other methods of fabrication and materials within the purview of one of ordinary skill in the art are contemplated.

Acoustic resonators, and particularly BAW resonators, can be employed in a variety of configurations for RF and microwave devices such as filters and oscillators operating in a variety of frequency bands. For use in mobile communication devices, one particular example of a frequency band of interest is the 850 MHz “cellular band.” In general, the size of a BAW resonator increases with decreasing frequency such that a BAW resonator for the 850 MHz band will be substantially larger than a similar a BAW resonator for the 2 GHz personal communication services (PCS) band. Meanwhile, in view of a continuing trends to miniaturize components of mobile communication device smaller, it may be conceptually imagined that a BAW resonator having a relatively large size may be cut in half, and the two halves—each of which may be considered to be a smaller acoustic resonator—may be stacked upon one another. An example of such a stacked BAW resonator is a DBAR.

In certain embodiments described below, a DBAR is formed with an acoustic stack having a distributed Bragg reflector (DBR) located below it, and an air cavity located above it. The DBAR can provide several benefits relative to FBARs and other forms of resonators, such as significant area reduction, and improved second harmonic (H2) removal. In addition, the DBR can provide several benefits to the DBAR, such as lowering its fabrication cost, improving its thermal conductivity, and improving its step-power handling while still minimizing the loss of acoustic energy into the substrate. On the other hand, the DBR may produce various shortcomings in the DBAR, such as reducing its parallel resistance Rp, increasing its series resistance Rs, and reducing its bandwidth. More generally, the DBR can enhance leakage of mechanical energy from the acoustic stack of the DBAR, so it can reduce certain aspects of performance compared to a DBAR using an underlying air cavity.

In other embodiments, a DBAR is formed with an acoustic stack having a DBR above it and an air cavity below it. The addition of a DBR above the acoustic stack can eliminate the need for a microcap, which can reduce the cost of manufacturing the DBAR. In addition, placing the DBR above the DBAR allows contact pads to be formed on top of the DBAR rather than on its sides, which can reduce the total area occupied by the DBAR. On the other hand, the DBR can reduce the performance of the DBAR by absorbing acoustic energy from the acoustic stack.

In still other embodiments, a DBAR is formed with an acoustic stack having a DBR both above and below it. These embodiments exhibit combined benefits and drawbacks from the DBR above and the DBR below. In addition, the symmetry arising from the two DBRs causes top and bottom portions of the DBAR to generate harmonics with offsetting phases that cancel each other out to improve H2 cancellation in a similar fashion to H2 cancellation in DBAR without any DBRs.

Although the addition of one or two DBRs can cause performance degradation, certain embodiments compensate for this degradation by using materials with intrinsically higher piezo-electric coupling coefficient (e.g. ZnO instead of AlN), or by doping piezoelectric layers of the DBAR with scandium ions or another rare earth metal. Examples of other rare earth metals that could be used include Lanthanum or various Lanthanum compounds such as La₃Ga₅SiO₁₄, and Erbium.

This doping can increase the piezo-electric coupling coefficient e₃₃ in piezo-electric layers of the DBAR to offset some of the degradation of electro-mechanical coupling coefficient kₜ² caused by the DBRs thus yielding unchanged electro-mechanical coupling coefficient kₜ² of the whole structure. It is the electro-mechanical coupling coefficient kₜ² of the whole structure that determines bandwidth of filter 100.

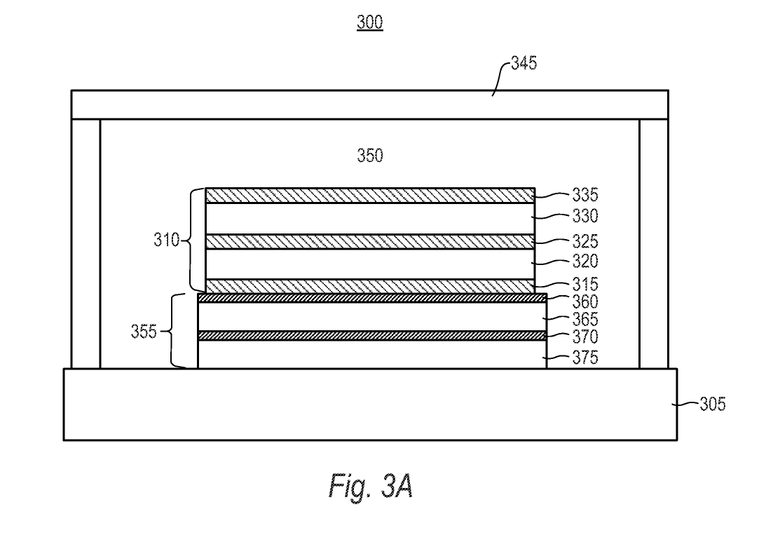

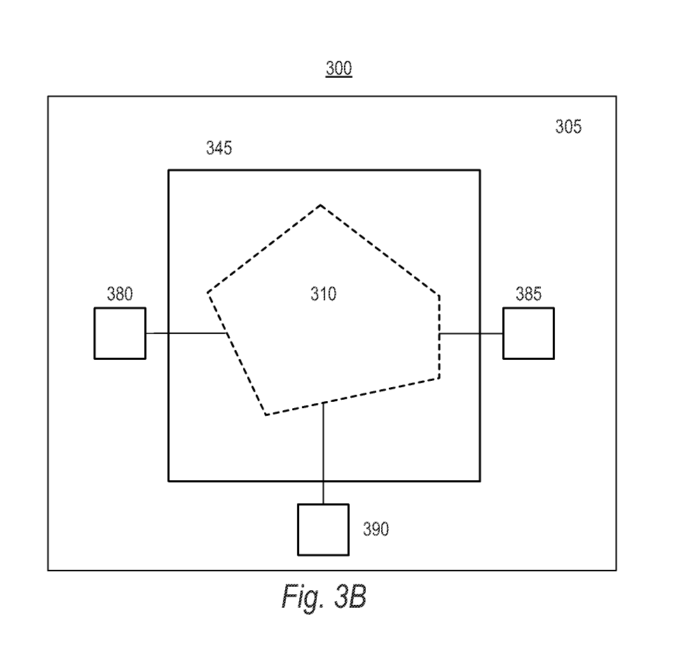

FIG. 3A is a cross-sectional view of acoustic resonator 300 and FIG. 3B is a top view of acoustic resonator 300 in accordance with a representative embodiment. In this embodiment, acoustic resonator 300 comprises a DBAR, and a DBR is formed below an acoustic stack of the DBAR. As illustrated by FIG. 3B, acoustic resonator 300 comprises an acoustic stack having an apodized pentagonal structure, i.e. a pentagon in which each side is of different length for the purpose of lateral mode suppression.

Referring to FIG. 3A, acoustic resonator 300 comprises a substrate 305, an acoustic stack 310, a DBR 355, and a microcap 345 separated from the acoustic stack 310 by a gap 350, which may be unfilled (filled with air).

Substrate 305 can be formed of various types of semiconductor materials compatible with semiconductor processes, such as silicon (Si), gallium arsenide (GaAs), indium phosphide (InP), or the like, which is useful for integrating connections and electronics, thus reducing size and cost.

Acoustic stack 310 comprises a first electrode 315, a first piezoelectric layer 320 formed on first electrode 315, a second electrode 325 formed on first electrode 315, a second piezoelectric layer 330 formed on second electrode 325, and a third electrode 335 formed on second piezoelectric layer 330.

First, second and third electrodes 315, 325, and 335 can be formed of various conductive materials, such as metals compatible with semiconductor processes, including tungsten (W), molybdenum (Mo), aluminum (Al), platinum (Pt), ruthenium (Ru), niobium (Nb), or hafnium (Hf), for example. First, second and third electrodes 315, 325, and 335 can also be formed with conductive sub-layers or in combination with other types of layers, such as temperature compensating layers. In addition, first, second and third electrodes 315, 325, and 335 can be formed of the same material, or they can be formed of different materials.

Third electrode 335 can further comprise a passivation layer (not shown), which can be formed of various types of materials, including aluminum nitride (AlN), silicon carbide (SiC), BSG, SiO₂, SiN, polysilicon, and the like. The thickness of the passivation layer should generally be sufficient to insulate the layers of acoustic stack 310 from the environment, including protection from moisture, corrosives, contaminants, and debris.

First, second and third electrodes 315, 325, and 335 are electrically connected to external circuitry via corresponding contact pads 380, 385, and 390 shown in FIG. 3B. The contact pads are typically formed of a conductive material, such as gold or gold-tin alloy. Although not shown in FIG. 3A, the connections between these electrodes and the corresponding contact pads extend laterally outward from acoustic stack 310. The connections typically pass through or under the sides of microcap 345. The connections are generally formed of a suitable conductive material, such as a gold thread.

First and second piezoelectric layers 320 and 330 are typically formed of a thin film piezoelectric compatible with semiconductor processes, such as aluminum nitride (AlN), zinc oxide (ZnO), or lead zirconium titanate (PZT). They can also be formed of other piezoelectric materials such as gallium nitride (GaN), indium phosphate (InP), or gallium phosphate (GaP). In some embodiments, first and second piezoelectric layers 320 and 330 are formed on a seed layer (not shown) disposed over respective upper surfaces of first and second electrodes 315 and 325. The seed layer can be formed of Al, for instance, to foster growth of AlN for first and second piezoelectric layers 320 and 330.

DBR 355 is grown on the top of substrate 305 and provides acoustic isolation between substrate 305 and acoustic stack 310. DBR 355 comprises a plurality of Bragg layers with differing acoustic impedances. In particular, DBR 355 comprises a first Bragg layer 360 having relatively low acoustic impedance, a second Bragg layer 365 having relatively high acoustic impedance, a third Bragg layer 370 having relatively low acoustic impedance, and a fourth Bragg layer 375 having relatively high acoustic impedance. These differing acoustic impedances can be obtained, for instance, by forming first and third Bragg layers 360 and 370 of a relatively soft material, and forming second and fourth Bragg layers 365 and 375 of a relatively hard material. Notably, the number of layers in DBR does not need to be limited to 4, but in general is determined by a tradeoff between expected mirror performance (the more layers the better) and cost and processing issues (the fewer layers the cheaper and more straightforward mirror growth and post-processing).

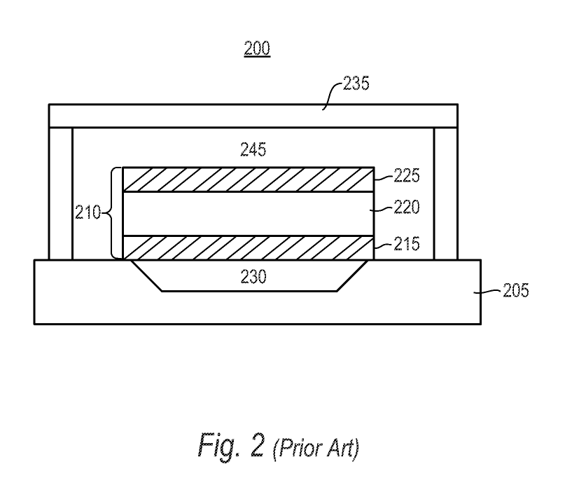

In general, the amount of acoustic isolation provided by DBR 355 depends on the contrast between the acoustic impedances of the adjacent Bragg layers, with a greater amount of contrast creating better acoustic isolation. In some embodiments, the Bragg layers in DBR 355 are formed of a pair of dielectric materials having contrasting acoustic impedances. One example of such a pair is carbon-doped silicon oxide (CDO) and silicon nitride. A benefit of this pair is that it can be grown in a single machine by depositing CDO onto a silicon wafer within a first chamber, moving the wafer to a second chamber, depositing silicon nitride on the wafer in the second chamber, moving the wafer back into the first chamber, and so on. This process can be cheaper (e.g., about 10%) than producing an etched air cavity such as that shown in FIG. 2. Accordingly, in certain applications, DBR 355 can serve as a cost effective substitute for an air cavity. DBR 355 can be fabricated using various alternative techniques, an example of which is described in U.S. Pat. No. 7,358,831 to Larson, III, et al., which is hereby incorporated by reference.

In addition to potentially lowering the cost of acoustic resonator 300, DBR 355 can also improve its thermal conductivity and step power handling. However, one shortcoming of DBR 355 is that it is an imperfect acoustic mirror, which causes energy to be lost both vertically into the substrate 305 and laterally along the layers of DBR 355. This loss of energy and extension of mechanical motion from the resonator region to the surroundings tends to diminish signal power and reduce bandwidth. For example, in one embodiment, DBR 355 reduces the bandwidth of an input signal from 100 MHz to 80 MHz.

Microcap 345 is formed over the top of acoustic stack 310 to form gap 350. Gap 350 provides acoustic isolation between acoustic stack 310 and surrounding structures, and microcap 345 protects acoustic resonator 300 against damage from environmental factors such as humidity, debris, and so on. In certain embodiments, microcap 345 is formed by etching a cavity in a silicon wafer and then performing a wafer bonding process to connect it to substrate 305. In other embodiments, microcap 345 is formed by attaching an annular gasket to substrate 305 and then covering the gasket with a silicon wafer. Microcap 345 can account for a significant part of the cost of acoustic resonator 300. For instance, in some devices, the materials and processes required to form microcap 345 constitute as much as 30% of the total device cost.

FIG. 3B shows contact pads 380, 385, and 390 connected to respective first, second, and third electrodes 315, 325, and 335 of acoustic stack 310. These contacts pads are located on substrate 305 outside of microcap 345, and they are used to connect acoustic resonator 300 with external circuitry. Although the contact pads are used to form a simple electrical connection, they can constitute a proportionally large amount of chip area of acoustic resonator 300. Moreover, even where the area of acoustic stack 310 is reduced, the area of the contact pads tends to remain the same.

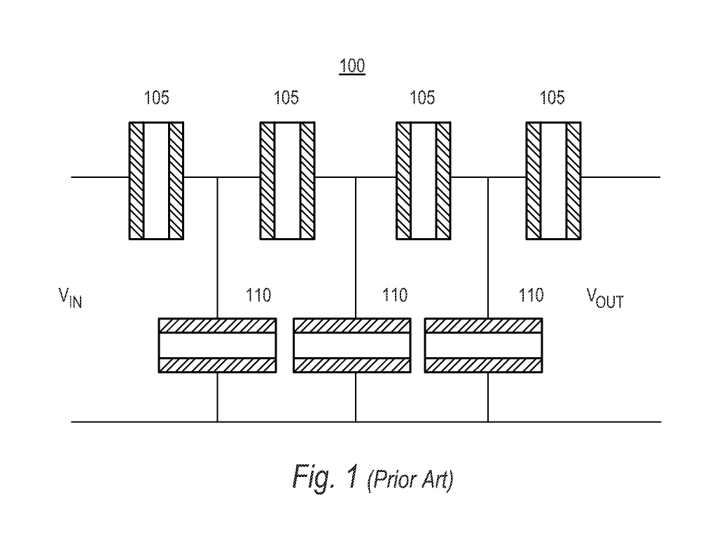

In a filter such as that illustrated in FIG. 1, contact pads are typically formed in only two of the seven acoustic resonators. In particular, they are formed in an acoustic resonator located at an input port, and an acoustic resonator located at an output port. The other acoustic resonators can be connected to each other by internal connections without the use of contact pads.

During typical operation of acoustic resonator 300, contact pads 380 and 390 are connected to the same voltage so that first and third electrodes 315 and 335 have the same level. Meanwhile, contact pad 385 is connected to a different voltage from contact pads 380 and 390 so that second electrode 325 has a different voltage level from first and third electrodes 315 and 335. In one example, contact pads 380 and 390 are connected to a common reference voltage such as ground, while contact pad 385 is connected to an input signal. Alternatively, contact pad 385 can be connected to ground while contact pads 380 and 390 are both connected to an input signal.

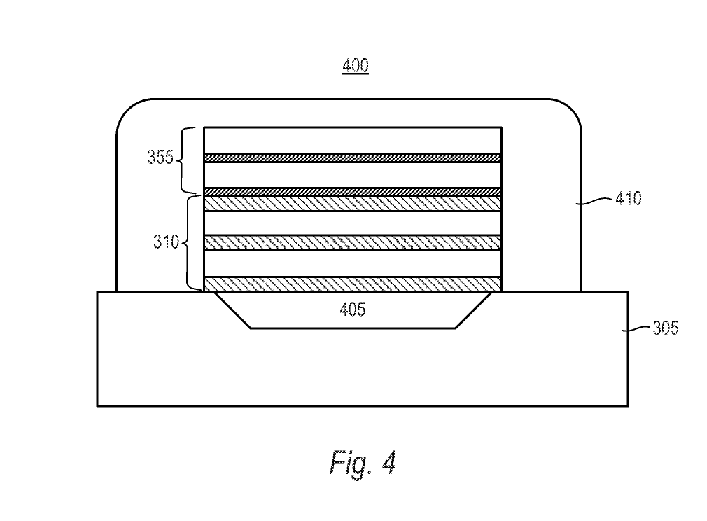

FIG. 4 is a cross-sectional view illustrating an acoustic resonator 400 in accordance with another representative embodiment. In the embodiment of FIG. 4, a DBR is formed above an acoustic stack of a DBAR.

Referring to FIG. 4, acoustic resonator 400 comprises substrate 305, acoustic stack 310, and DBR 355. These features are formed similar to FIG. 3A, except that DBR 355 is formed above acoustic stack 310, and a cavity 405 is formed in substrate 305. The cavity 405 is typically unfilled (filled with air).

Acoustic resonator 400 further comprises a mold 410 formed over substrate 305, acoustic stack 310, and DBR 355. Mold 410 may hermetically seal and protect acoustic resonator 400, eliminating the need for a microcap such as that illustrated in FIG. 3A. Mold 410 is typically formed by depositing a molding material over substrate 305, acoustic stack 310, and DBR 355, and then curing the molding material. The molding material can take various forms, such as polyimide, room-temperature vulcanizing rubber (RTV), or glass-loaded epoxy, to name but a few. In applications using hermetic encapsulation, mold 410 may additionally comprise a thin sealing layer of metal applied as a coating to an external surface of the cured molding material. Suitable metals include aluminum and gold, for example. The additional metal sealing layer substantially reduces the porosity of mold 410.

Cavity 405 provides acoustic isolation between substrate 305 and a bottom part of acoustic stack 310. Cavity 405 is generally formed by depositing a sacrificial layer in substrate 305 prior to the formation of acoustic stack 310, and then removing the sacrificial layer after the formation of acoustic stack 310. Various techniques for forming cavities in a substrate are described, for example, in U.S. Pat. No. 7,345,410 to Grannen et al., or U.S. Pat. No. 6,060,818 to Ruby, et al., the disclosures of which are hereby incorporated by reference.

DBR 355 provides acoustic isolation between a top part of acoustic stack 310 and mold 410. DBR 355 can be formed using techniques similar to those described above in relation to FIG. 3A.

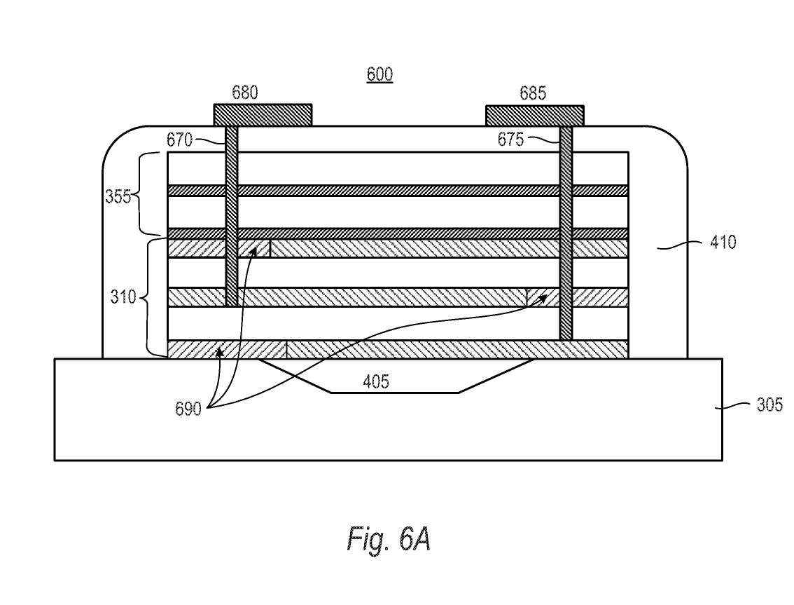

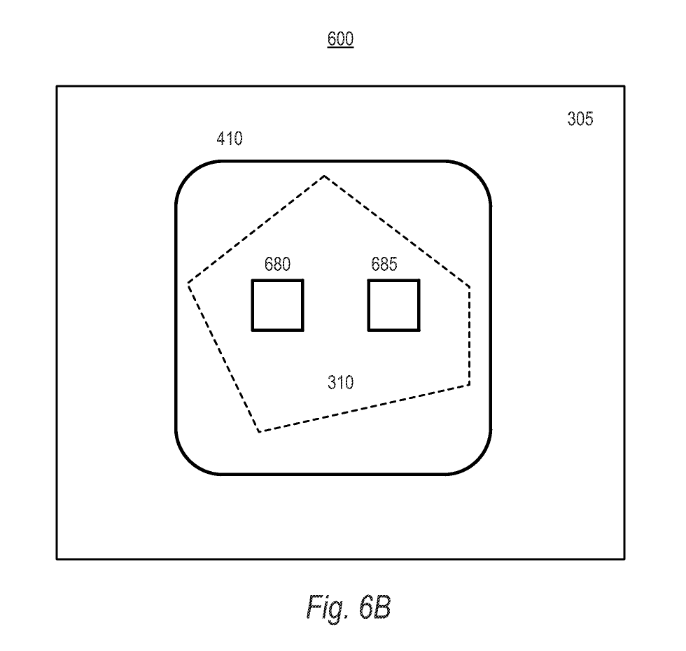

In some embodiments, the electrodes of acoustic stack 310 are connected to external contact pads located on the sides of mold 410. Such connections can be formed, for example, by a conductive material passing through or below the sidewalls of mold 410. In addition, as will be described with reference to FIG. 6, the electrodes of acoustic stack 310 can also be connected to contact pads located above mold 410. Such connections can be made, for instance, by constructing vias or other vertical structures that pass through a top part of mold 410.

Because DBR 355 is an imperfect mirror, some of the energy in acoustic stack 310 can be absorbed into mold 410 via DBR 355 or can leak out laterally along the layers of DBR 355. This can reduce the power and bandwidth of transmitted signals, deteriorating the performance of filter 100 comprising acoustic resonators 400. However, because acoustic resonator 400 does not include a microcap, it can potentially be formed at a lower cost than acoustic resonator 300. In addition, by eliminating various features associated with the microcap, it can be formed in a smaller area (e.g., 10% less) than acoustic resonator 300. Moreover, the area of acoustic resonator 400 can be further reduced by forming contact pads on top of mold 410.

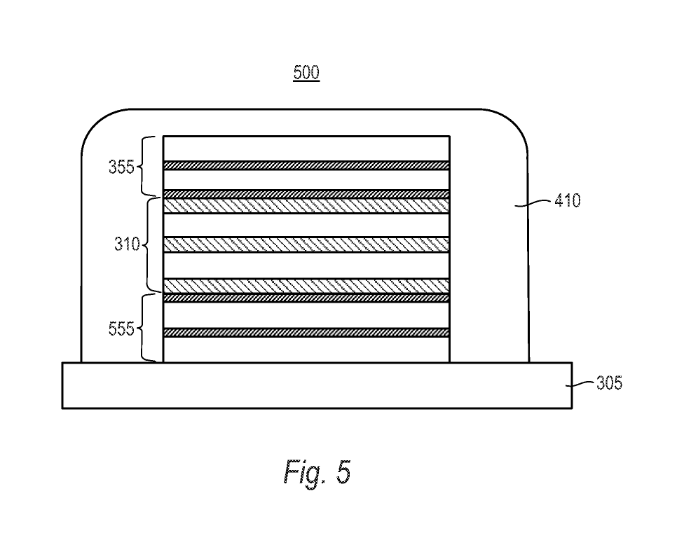

FIG. 5 is a cross-sectional view illustrating an acoustic resonator 500 in accordance with still another representative embodiment. In the embodiment of FIG. 5, a first DBR is formed above an acoustic stack of a DBAR, and a second DBR is formed below the acoustic stack of the DBAR.

Referring to FIG. 5, acoustic resonator 500 comprises substrate 305, acoustic stack 310,

DBR 355, mold 410, and another DBR 555. Among the features of acoustic resonator 500, substrate 305, acoustic stack 310, DBR 355, and mold 410 are formed similar to the embodiment of FIG. 4. Accordingly a further description of these features will be omitted in order to avoid redundancy.

DBR 555 is formed in substrate 305 below acoustic stack 310. DBR 555 can be formed similar to DBR 355 of FIG. 3A. Accordingly, DBR 555 provides acoustic isolation between acoustic stack 310 and substrate 305.

By including a DBR both above and below acoustic stack 310, acoustic resonator 500 achieves several of the benefits and drawbacks of acoustic resonators 300 and 400, each of which includes only one DBR. For instance, acoustic resonator 500 can achieve improved thermal conductivity, lower cost, and reduced size. In addition, it can achieve improved mechanical stability by omitting air cavities, and it can be of reduced size by omitting a microcap and/or placing contact pads above mold 410.

Acoustic resonator 500 can also achieve superior H2 cancellation compared with acoustic resonators 300 and 400 due to symmetry between DBR 355 and DBR 555. This can be explained by the fact that a DBAR operates in lambda mode, as contrasted with, for example, the half-lambda mode of an FBAR. The lambda mode is characterized by the top half of the DBAR oscillating in an opposite vertical direction from the bottom part of the DBAR. Consequently, top and bottom portions of the DBAR generate harmonics with offsetting phases. For example, the top half can generate a second harmonic with a positive phase while the bottom half generates a second harmonic with a negative phase. Taken together, the offsetting harmonics cancel each other. Because the top and bottom halves of acoustic resonator 500 are more symmetrical than the top and bottom halves of acoustic resonators 300 and 400, the offsetting harmonics in acoustic resonator 500 are relatively well matched, which produces improved H2 cancellation.

FIG. 6A is a cross-sectional view illustrating an acoustic resonator 600 having contact pads formed above an acoustic stack in accordance with a representative embodiment. The basic structure of acoustic resonator 600 is substantially the same as acoustic resonator 400 of FIG. 4. However, acoustic resonator 600 could be modified to have the same basic structure as acoustic resonator 500; that is, it could comprise of a DBAR placed between bottom and top DBRs.

Referring to FIG. 6A, acoustic resonator 600 comprises substrate 305, cavity 405 formed in substrate 305, acoustic stack 310 formed on substrate 305, and DBR 355 formed on acoustic stack 310. Acoustic stack 310 further comprises a planarization dielectric 690 formed in each of first, second, and third electrodes 315, 325, and 335. Planarization dielectric 690 can be formed of a material such as non-etching borosilicate glass (NEBSG). Planarization dielectric 690 defines boundaries of an active portion of acoustic resonator 600. In general, planarization of first, second and third electrodes 315, 325 and 335 is not necessary and it increases the total cost when performed, but it simplifies the processing and improves the quality of materials subsequently grown over the planarized layers. Mold 410 is formed on substrate 305 to cover acoustic stack 310 and DBR 355.

Acoustic resonator 600 further comprises first and second vias 670 and 675 and corresponding first and second contact pads 680 and 685 connected to the electrodes of acoustic stack 310. First and second vias 670 and 675 are formed outside the active portion of acoustic resonator 600 to avoid interfering with its performance. First via 670 is connected to first and third electrodes 315 and 335 of acoustic stack 310 to provide a common signal to these electrodes, and second via 675 is connected to second electrode 325 of acoustic stack 310. In some configurations, first via 670 provides a common reference voltage, such as ground, to both first and third electrodes 315 and 335, while second via 675 provides a time varying input signal to second electrode 325. First via 670 is connected to first contact pad 680 on top of mold 410, and second via 675 is connected to second contact pad 685 on top of mold 410. This allows electrical signals applied to first and second contact pads 680 and 685 to be supplied to first, second and third electrodes 315, 325 and 335.

First and second vias 670 and 675 can be formed by creating via holes in mold 410, DBR 355, and acoustic stack 310, depositing an insulator in the via holes to line their sidewalls, and then depositing a conductive material in the via holes to create a conductive path therethrough. In some embodiments, the via holes are formed by an etching process performed after mold 410 is cured. In other words, they are formed by successively etching mold 410, DBR 355, and acoustic stack 310. Alternatively, first and second vias 670 and 675 can be formed by etching processes performed at various intermediate steps in the formation of acoustic stack 310, DBR 355, and mold 410.

As an alternative to forming vias straight through the DBR 355 and through the mold 410, vias and intermediate pads over the active resonator can be formed after the DBR 355 is grown but before mold deposition. Such a configuration would allow for electrical testing of un-molded resonators and would allow for more straightforward inspection of possibly faulty resonators. After such tests are concluded, the parts can be molded and vias through the mold can be etched to connect to the intermediate pads on top of DBR 355. The final pads would be placed on the top of the mold 410.

FIG. 6B is a top view of acoustic resonator 600 in accordance with a representative embodiment. In this embodiment, acoustic stack 310 has an apodized pentagonal shape, and first and second contact pads 680 and 685 are formed on mold 410 above acoustic stack 310.

Comparing acoustic resonator 600 of FIG. 6B with acoustic resonator 300 of FIG. 3B, the placement of first and second contact pads 680 and 685 significantly reduces the area occupied by acoustic resonator 600. It also simplifies the design of acoustic resonator 600 by using a single contact pad to supply the same signal to first and second electrodes 315 and 325.

In addition to reducing the size of acoustic resonator 600, first and second contact pads 680 and 685 can also provide connections to other devices using various package configurations. As examples, acoustic resonator 600 could be connected to other integrated circuit (IC) packages in a package on package (PoP) configuration, a ball grid array configuration, and so on.

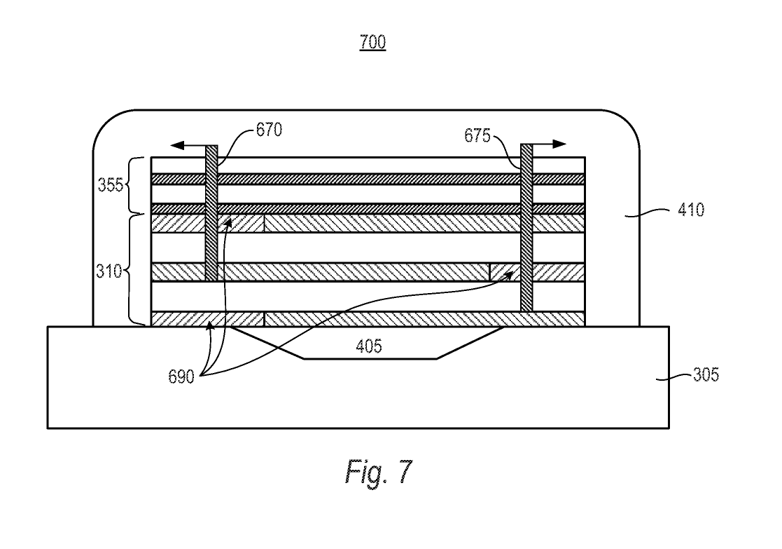

FIG. 7 is a cross-sectional view illustrating an acoustic resonator 700 having contact pads formed above an acoustic stack in accordance with another representative embodiment. This embodiment is similar to that of FIG. 6, except that first and second vias 670 and 675 extend only to the top of DBR 355, but not through mold 410. As indicated by small arrows in FIG. 7, first and second vias 670 and 675 can be connected to laterally extending wires. They can also be connected to vertically extending wires.

The configuration of first and second vias 670 and 675 can allow electrical connections to be formed in different ways, such as connecting multiple DBARs to each other in a filter. As one example, in a ladder filter comprising multiple acoustic resonators, contact pads may be formed in only a subset of the acoustic resonators. The remaining resonators may be connected to each other via internal connections such as those illustrated in FIG. 7. Alternatively, the remaining resonators may be connected directly by laterally extending metal layers of DBAR 700. Advantages of connecting resonators in DBAR's metal layers is an improved robustness of the mirror stack and simplified connectivity scheme, but a disadvantage is that extending metal layers laterally can increase leakage of acoustic energy resulting in degraded insertion loss of filter 100 comprising acoustic resonators 700.

As indicated in the descriptions of FIGS. 3 through 5, a DBR is generally an imperfect acoustic mirror. Accordingly, DBRs 355 and 555 allow a certain amount of acoustic energy to be absorbed into substrate 305 and/or mold 410. This loss of energy and mechanical confinement produces a reduction in the insertion loss and bandwidth of filter 100 comprising of acoustic resonators 300 through 500.

One measure of this decreased mechanical confinement is electro-mechanical coupling coefficient kₜ² of acoustic resonators 300 through 500. The electro-mechanical coupling coefficient kₜ² is a ratio of mechanical energy transmitted through a piezoelectric layer of an acoustic resonator to the electrical energy received by the acoustic resonator. In other words, the electro-mechanical coupling coefficient kₜ² indicates the efficiency with which an acoustic resonator converts electrical energy into mechanical energy.

In some applications, a target range for electro-mechanical coupling coefficient kₜ² is between about 7% and 10%. However, the stacking of resonator structures, as in a DBAR, can reduce the electro-mechanical coupling coefficient kₜ² by about 0.5%. In addition, the presence of each DBR can further reduce the electro-mechanical coupling coefficient kₜ² by about 0.5%. Consequently, the structures shown in FIGS. 3 through 7 can potentially reduce the electro-mechanical coupling coefficient kₜ² from a satisfactory value such as 7%, to an unsatisfactory value such as 5.5%.

One way to compensate for reduction in the electro-mechanical coupling coefficient kₜ² is to use different than AlN piezo-electric material, like ZnO. It has been demonstrated that SMRs and FBARs with ZnO piezo-electric layer exhibit ˜1% larger kₜ² than similar devices made with AlN piezo-electric layer. Such increase would be sufficient to compensate for kₜ² degradation resulting from DBRs on the bottom and on the top of the resonator. Other alternative piezoelectrics include PZT, GaN, InP, and GaP, for example.

Another way to compensate for the reduction in electro-mechanical coupling coefficient kₜ² is by doping the piezoelectric layer of an acoustic resonator with scandium ions or another rare earth metal. For instance, in an acoustic resonator comprising a piezoelectric layer formed of AlN, doping with scandium ions can increase the electro-mechanical coupling coefficient kₜ² by as much as two times compared with pure AlN. A typical doping range for achieving this increase is about 5-10% scandium doping. Scandium-doped AlN can be manufactured, for example, by simultaneous sputtering of Aluminum and Scandium in Nitrogen containing atmosphere. Power density and substrate temperature during the sputtering process determine the amount of scandium ions incorporated into AlN, thus determining the piezo-electric coupling coefficient e₃₃ of the resulting material.

As alternatives, other types of rare earth metals could be used to dope the AlN, and other types of piezoelectrics can be doped with scandium ions or rare earth metals. Examples of alternative piezoelectrics include ZnO, PZT, GaN, InP, and GaP. Examples of other rare earth metals that could be used include lanthanum or various lanthanum compounds such as La₃Ga₅SiO₁₄, and erbium.

In view of the benefits provided by scandium doping, certain embodiments comprise acoustic resonators 300 through 700 in which the piezoelectric layers of acoustic stack 310 are doped with scandium ions. Moreover, scandium doping can also be used to improve the performance of other resonator structures, such as coupled resonator filters (CRFs), solidly mounted resonators (SMRs), FBARs, and others. Such resonators find ready application in various devices, such as wideband filters, multiplexers, and others.

Results from quantum-mechanical simulation in Tasnadi et al. [Physical Review Letter, Vol. 104, p 137601 (2010)] suggest that piezo-electric coefficient e₃₃ in Sc doped AlN increases from ˜1.5 C/m² to ˜3 C/m² when Sc concentration increases from 0 to 50%. Over the same range of Sc concentrations the elastic constant c₃₃ decreases from ˜375 GPa to ˜125 GPa. Because kₜ² is determined by the ratio e₃₃²/c₃₃ (where dielectric permittivity coefficient under constant stress remains the same), a total of up to 12× increase of kₜ² could be expected in heavily (50%) Sc-doped AlN as compared to un-doped AlN. Most likely such material (50% Sc-doped AlN) won't be practical, because typically viscous loss increases with decreasing c₃₃ coefficient, resulting in resonators with very poor Q-values. However, for modestly 5% Sc-doped AlN the expected increase of electro-mechanical coupling coefficient kₜ² of the whole structure would be −20%, that is, for example, kₜ² would increase from 5% to 6%. Such increase would be enough to compensate for kₜ² degradation resulting from DBRs on the bottom and on the top of the resonator.

The devices illustrated in FIGS. 3 through 7 could be modified to replace the DBARs with stacked bulk acoustic resonators (SBARs). As an example, acoustic resonator 600 could be modified such that first and third electrodes 315 and 335 are used as separate electrodes while electrode 325 is grounded. In such an example, first electrode 315 can be used as an input electrode while second electrode 325 is used as an output electrode. Such a modified device could provide many benefits similar to those described above with reference to FIGS. 3 through 7. Moreover, such a modified device could be employed in similar applications, such as the ladder filter illustrated in FIG. 1.

Although example embodiments have been disclosed herein, those skilled in the art will recognize that many variations that are in accordance with the present teachings are possible and remain within the scope of the appended claims. The embodiments therefore are not to be restricted except within the scope of the appended claims.

What is claimed is:

1. A device, comprising:
a substrate;
an acoustic stack comprising a first electrode formed on the substrate, a first piezoelectric layer formed on the first electrode, a second electrode formed on the first piezoelectric layer, a second piezoelectric layer formed on the second electrode, and a third electrode formed on the second piezoelectric layer; and
a distributed Bragg reflector formed on the third electrode.

2. The device of claim 1, further comprising an air cavity formed in the substrate below the first electrode.

3. The device of claim 1, further comprising a second distributed Bragg reflector formed on the substrate below the third electrode.

4. The device of claim 1, wherein the distributed Bragg reflector comprises alternating layers of carbon doped silicon oxide and silicon nitride.

5. The device of claim 1, wherein at least one of the first and second piezoelectric layers is doped with about 5-10% scandium ions.

6. The device of claim 1, wherein at least one of the first and second piezoelectric layers comprises aluminum nitride doped with scandium ions.

7. The device of claim 1, further comprising a mold formed on the substrate over the acoustic stack and the distributed Bragg reflector.

8. The device of claim 7, further comprising electrical contact pads formed on the mold.

9. The device of claim 8, further comprising a via forming a common electrical connection with the first and third electrodes and passing through the mold to connect one of the contact pads to the first and third electrodes.

10. The device of claim 1, wherein at least one of the first and second piezoelectric layers comprises zinc oxide.

11. A device, comprising:
a substrate;
a distributed Bragg reflector formed over the substrate; and
an acoustic stack formed on the substrate over the distributed Bragg reflector, the acoustic stack comprising a first electrode, a first piezoelectric layer formed on the first electrode, a second electrode formed on the first piezoelectric layer, a second piezoelectric layer formed on the second electrode, and a third electrode formed on the second piezoelectric layer.

12. The device of claim 11, wherein at least one of the first and second piezoelectric layers comprises aluminum nitride, zinc oxide, lead zirconium titanate, gallium nitride, indium phosphate, or gallium phosphate.

13. The device of claim 11, further comprising a silicon microcap formed over the acoustic stack.

14. The device of claim 11, wherein the first and second piezoelectric layers comprise aluminum nitride, the first through third electrodes comprise tungsten, and the distributed Bragg reflector comprises alternating layers of carbon doped silicon oxide and silicon nitride.

15. The device of claim 14, wherein the first and second piezoelectric layers are doped with scandium ions.

16. The device of claim 12, wherein at least one of the first and second piezoelectric layers is doped with scandium, lanthanum, or erbium.

17. The device of claim 14, wherein the first and third electrodes are configured to receive a ground voltage and the second electrode is configured to receive a time varying input voltage.

18. A filter, comprising:
a plurality of series connected acoustic resonators between an input terminal and an output terminal; and
a plurality of shunt acoustic resonators connected in parallel between the series connected acoustic resonators and a reference voltage;
wherein at least one of the series connected acoustic resonators or the shunt acoustic resonators comprises a substrate, an acoustic stack comprising a first electrode formed on the substrate, a first piezoelectric layer formed on the first electrode, a second electrode formed on the first piezoelectric layer, a second piezoelectric layer formed on the second electrode, and a third electrode formed on the second piezoelectric layer, and a distributed Bragg reflector formed on the third electrode.

19. The filter of claim 18, wherein the at least one of the series connected acoustic resonators or the shunt acoustic resonators further comprises a distributed Bragg reflector formed over the substrate below the first electrode.

20. The filter of claim 18, wherein at least one of the series connected acoustic resonators or the shunt acoustic resonators is located at the input terminal or the output terminal and comprises electrical contact pads formed above the acoustic stack.

21. The filter of claim 20, wherein the electrical contact pads are connected to the first, second, and third electrodes through a plurality of vias penetrating the acoustic stack.

22. The filter of claim 21, further comprising a plastic mold formed on the substrate over the acoustic stack, and the distributed Bragg reflector.

23. The filter of claim 18, wherein at least one of the first and second piezoelectric layers comprises zinc oxide.
